(19) United States
(12) Patent Application Publication
(10) Pub. No.: US 2007/0063180 A1
(43) Pub. Date: Mar. 22, 2007

(54) Electrically rewritable non-volatile memory element and method of manufacturing the same

(75) Inventors: Isamu Asano, Tokyo (JP); Natsuki Sato, Tokyo (JP); Kiyoshi Nakai, Tokyo (JP)

Correspondence Address: MCDERMOTT WILL & EMERY LLP, 600 13TH STREET, N.W., WASHINGTON, DC, 20005-3096, US

(73) Assignee: ELPIDA MEMORY, INC.

(21) Appl. No.: 11/516,510

(22) Filed: Sep. 7, 2006

(30) Foreign Application Priority Data
Sep. 7, 2005 (JP) 2005-259934

(51) Int. Cl. H01L 29/04

(52) U.S. Cl. 257/3

(57) ABSTRACT

A non-volatile memory element includes a recording layer that includes a phase change material, a lower electrode provided in contact with the recording layer, an upper electrode provided in contact with a portion of the upper surface of the recording layer, a protective insulation film provided in contact with the other portion of the upper surface of the recording layer, and an interlayer insulation film provided on the protective insulation film. High thermal efficiency can thereby be obtained because the size of the area of contact between the recording layer and the upper electrode is reduced. Providing the protective insulation film between the interlayer insulation film and the upper surface of the recording layer makes it possible to reduce damage sustained by the recording layer during patterning of the recording layer or during formation of the through-hole for exposing a portion of the recording layer.

### TECHNICAL FIELD

The present invention relates to an electrically rewritable non-volatile memory element and to a method of manufacturing the element. More specifically, the present invention relates to an electrically rewritable non-volatile memory element having a recording layer that includes phase change material, and to a method of manufacturing the element.

### BACKGROUND OF THE INVENTION

Personal computers and servers and the like use a hierarchy of memory devices. There is lower-tier memory, which is inexpensive and provides high storage capacity, while memory higher up the hierarchy provides high-speed operation. The bottom tier generally consists of magnetic storage such as hard disks and magnetic tape. In addition to being non-volatile, magnetic storage is an inexpensive way of storing much larger quantities of information than solid-state devices such as semiconductor memory. However, semiconductor memory is much faster and can access stored data randomly, in contrast to the sequential access operation of magnetic storage devices. For these reasons, magnetic storage is generally used to store programs and archival information and the like, and, when required, this information is transferred to main system memory devices higher up in the hierarchy.

Main memory generally uses dynamic random access memory (DRAM) devices, which operate at much higher speeds than magnetic storage and, on a per-bit basis, are cheaper than faster semiconductor memory devices such as static random access memory (SRAM) devices.

Occupying the very top tier of the memory hierarchy is the internal cache memory of the system microprocessor unit (MPU). The internal cache is extremely high-speed memory connected to the MPU core via internal bus lines. The cache memory has a very small capacity. In some cases, secondary and even tertiary cache memory devices are used between the internal cache and main memory.

DRAM is used for main memory because it offers a good balance between speed and bit cost. Moreover, there are now some semiconductor memory devices that have a large capacity. In recent years, memory chips have been developed with capacities that exceed one gigabyte. DRAM is volatile memory that loses stored data if its power supply is turned off. That makes DRAM unsuitable for the storage of programs and archival information. Also, even when the power supply is turned on, the device has to periodically perform refresh operations in order to retain stored data, so there are limits as to how much device electrical power consumption can be reduced, while yet a further problem is the complexity of the controls run under the controller.

Semiconductor flash memory is high capacity and non-volatile, but requires high current for writing and erasing data, and write and erase times are slow. These drawbacks make flash memory an unsuitable candidate for replacing DRAM in main memory applications. There are other non-volatile memory devices, such as magnetoresistive random access memory (MRAM) and ferroelectric random access memory (FRAM), but they cannot easily achieve the kind of storage capacities that are possible with DRAM.

Another type of semiconductor memory that is being looked to as a possible substitute for DRAM is phase change random access memory (PRAM), which uses phase change material to store data. In a PRAM device, the storage of data is based on the phase state of phase change material contained in the recording layer. Specifically, there is a big difference between the electrical resistivity of the material in the crystalline state and the electrical resistivity in the amorphous state, and that difference can be utilized to store data.

This phase change is effected by the phase change material being heated when a write current is applied. Data is read by applying a read current to the material and measuring the resistance. The read current is set at a level that is low enough not to cause a phase change. Thus, the phase does not change unless it is heated to a high temperature, so data is retained even when the power supply is switched off.

In order for the phase change material to be efficiently heated by the write current, it is preferable to adopt a configuration that makes it as difficult as possible for heat generated by application of the write current to be released.

However, since the entire upper surface of the recording layer composed of the phase change material is in contact with a metal layer in the non-volatile memory element described in “Scaling Analysis of Phase-Change Memory Technology,” A. Pirovano, A. L. Lacaita, A. Benvenuti, F. Pellizzer, S. Hudgens, and R. Bez, IEEE 2003, the heat generated when the write current is applied is easily released to the side of the metal layer, creating drawbacks of low thermal efficiency. Reduced thermal efficiency leads to increased power consumption and increased write times.

However, an upper electrode is provided between the metal layer and the recording layer composed of the phase change material in the non-volatile memory element described in “Writing Current Reduction for High-density Phase-change RAM,” Y. N. Hwang, S. H. Lee, S. J. Ahn, S. Y. Lee, K. C. Ryoo, H. S. Hong, H. C. Koo, F. Yeung, J. H. Oh, H. J. Kim, W. C. Jeong; J. H. Park, H. Horii, Y. H. Ha, J. H. Yi, G. H. Hoh, G. T. Jeong, H. S. Jeong, and Kinam Kim,” IEEE 2003 and “An Edge Contact Type Cell for Phase Change RAM Featuring Very Low Power Consumption,” Y. H. Ha, J. H. Yi, H. Horii, J. H. Park, S. H. Joo, S. O. Park, U-In Chung, and J. T. Moon, 2003 Symposium on VLSI Technology Digest of Technical Papers. Since direct contact between the recording layer and the metal layer can be prevented by providing the upper electrode in the manner described above, it becomes possible to reduce the amount of heat released to the side of the metal layer.

However, the entire upper surface of the recording layer is in contact with the upper electrode in the non-volatile memory element described in later two papers. The requirement that the upper electrode be composed of a conductive material makes it difficult to significantly reduce the coefficient of thermal conductivity of the upper electrode itself. Since the write current flows in scattered fashion when the entire upper surface of the recording layer is in contact with the upper electrode, it is difficult to adequately increase thermal efficiency.

In the non-volatile memory element described in Japanese Patent Application Laid Open Nos. 2004-289029 and 2004-349709, however, the upper electrode is provided to the upper surface of the recording layer, but the entire upper surface of the recording layer is not in contact with the upper electrode, and only a portion of the upper surface is in contact with the upper electrode. This type of structure makes it possible to increase thermal efficiency by reducing the amount of heat released to the side of the upper electrode.

Another method for increasing thermal efficiency has been proposed (see U.S. Pat. No. 5,536,947) in which a thin-film insulating layer (filament dielectric film) is provided between a recording layer that includes a phase-change material, and a lower electrode that acts as a heater; forming a pinhole by inducing dielectric breakdown in the thin-film insulating layer; and utilizing the pinhole as a current path. Since the diameter of the pinhole formed by dielectric breakdown can be made far smaller than the diameter of a through-hole that can be formed by lithography, the area of heat generation can be made extremely small. This makes it possible for the phase change material to be efficiently heated by the write current, resulting in the ability not only to reduce the write current, but also to increase the write speed.

However, the entire upper surface of the recording layer is also in contact with the upper electrode in the non-volatile memory element described in U.S. Pat. No. 5,536,947. It is therefore impossible to reduce the amount of heat released to the metal layer positioned above the recording layer.

The non-volatile memory elements described in above three papers and U.S. Pat. No. 5,536,947 thus have drawbacks in having low thermal efficiency due to the large amount of heat released to the metal layer positioned above the recording layer. In the non-volatile memory elements described in Japanese Patent Application Laid Open Nos. 2004-289029 and 2004-349709, however, only a portion of the upper surface of the recording layer is in contact with the upper electrode, and the other portions are covered by an interlayer insulation film. High thermal efficiency can therefore be realized.

However, in the non-volatile memory elements described in Japanese Patent Application Laid Open Nos. 2004-289029 and 2004-349709, there is a risk of the recording layer being significantly damaged during patterning of the recording layer, or during formation of a through-hole for exposing a portion of the recording layer. In other words, in a structure in which the entire upper surface of the recording layer is in contact with the upper electrode, damage during patterning can be prevented by performing the patterning while the recording layer and upper electrode are layered together. Since the through-hole does not reach the recording layer, almost no damage occurs when the through-hole is formed. In a structure in which the entire upper surface of the recording layer contacts the upper electrode, the upper electrode functions as a protective film for the recording layer during manufacturing, and damage to the recording layer is prevented.

However, the upper electrode cannot be made to function as a protective film in the case of a structure in which only a portion of the upper surface of the recording layer is in contact with the upper electrode, such as in the non-volatile memory elements described in Japanese Patent Application Laid Open Nos. 2004-289029 and 2004-349709. There is therefore a risk of significant damage to the recording layer occurring during patterning of the recording layer or formation of the through-hole, as described above.

### SUMMARY OF THE INVENTION

The present invention was developed in order to overcome these types of drawbacks. Accordingly, an object of the present invention is to provide an improved non-volatile memory element comprising a recording layer that includes a phase change material, and to provide a method for manufacturing the same.

Another object of the present invention is to provide a non-volatile memory element comprising a recording layer that includes a phase change material, wherein thermal efficiency is increased in the non-volatile memory element by reducing the amount of heat released to the metal layer positioned above the recording layer while minimizing damage to the recording layer during manufacturing; and to provide a method for manufacturing the non-volatile memory element.

Yet another object of the present invention is to provide a non-volatile memory element comprising a recording layer that includes a phase change material, wherein thermal efficiency is increased in the non-volatile memory element by focusing the distribution of the write current flowing to the recording layer while minimizing damage to the recording layer during manufacturing; and to provide a method for manufacturing the non-volatile memory element.

The above and other objects of the present invention can be accomplished by a non-volatile memory element comprises a recording layer that includes a phase change material, a lower electrode provided in contact with the recording layer, an upper electrode provided in contact with a portion of an upper surface of the recording layer, a protective insulation film provided in contact with another portion of the upper surface of the recording layer, and an interlayer insulation film provided on the protective insulation film.

The amount of heat released to the side of the upper electrode is reduced in the present invention because the area of contact between the recording layer and the upper electrode is reduced. The distribution of the write current flowing to the recording layer is also concentrated because of the small size of the area of contact between the recording layer and the upper electrode. Because of these aspects of the configuration of the non-volatile memory element of the present invention, thermal efficiency higher than that of the conventional technique can be obtained. Since a protective insulation film is also provided between the interlayer insulation film and the upper surface of the recording layer, it becomes possible to reduce the amount of damage sustained by the recording layer during patterning of the recording layer or formation of the through-hole for exposing a portion of the recording layer.

It is also preferred that the recording layer be composed of at least a first portion and a second portion, and that a thin-film insulating layer be provided between the first portion and the second portion. When this type of structure is employed, a pinhole formed in the thin-film insulating layer by dielectric breakdown becomes a current path. An extremely minute current path can therefore be formed whose size is not dependent on the precision of a lithography process. Since the thin-film insulating layer in which the pinhole is formed is held between two recording layers, heat transfer from a point at which heat is generated is effectively inhibited. As a result, it becomes possible to obtain extremely high thermal efficiency.

The method for manufacturing a non-volatile memory element according to a first aspect of the present invention comprises a first step for forming a recording layer that includes a phase change material, a second step for forming a pattern in the recording layer while the entire upper surface of the recording layer is covered by a protective insulation film, a third step for exposing a portion of the upper surface of the recording layer by removing a portion of at least the protective insulation film, and a fourth step for forming an upper electrode in contact with the portion of the upper surface of the recording layer.

The present invention makes it possible to create a non-volatile memory element in which the size of the area of contact between the recording layer and the upper electrode is reduced. The present invention also makes it possible to reduce the amount of damage sustained by the recording layer during patterning of the recording layer.

There is preferably a step for forming an interlayer insulation film on the protective insulation film after performing the second step and prior to performing the third step. The third step also preferably comprises a step for exposing a portion of the upper surface of the recording layer by forming a through-hole in the protective insulation film and the interlayer insulation film. It thereby becomes possible to reduce the amount of damage sustained by the recording layer during formation of the through-hole for exposing a portion of the recording layer.

It is also preferred that the third step comprise a step for forming a sidewall-forming insulation film whose end portion in a planar direction traverses the upper surface of the recording layer, and a step for exposing the portion of the upper surface of the recording layer by removing a portion of the protective insulation film using the sidewall-forming insulation film as a mask; and that the fourth step comprise a step for forming an upper electrode which covers a portion of the upper surface of the recording layer and at least a side surface of the sidewall-forming insulation film; and a step for etching back the upper electrode. The upper electrode is thereby given a ring shape, and since the width of the upper electrode is dependent upon the film thickness during film formation, the width of the upper electrode can be made smaller than the lithography resolution. The heat capacity of the upper electrode is therefore reduced even further, and the write current can be even further concentrated.

The method for manufacturing a non-volatile memory element according to another aspect of the present invention comprises a first step for forming a recording layer that includes a phase change material, a second step for covering the entire upper surface of the recording layer with a protective insulation film and an interlayer insulation film, a third step for exposing a portion of the upper surface of the recording layer by forming a through-hole in the protective insulation film and the interlayer insulation film, and a fourth step for forming an upper electrode in contact with the portion of the upper surface of the recording layer.

The present invention makes it possible to create a non-volatile memory element in which the size of the area of contact between the recording layer and the upper electrode is reduced. The interposition of the protective insulation film makes it possible to reduce the amount of damage sustained by the recording layer during formation of the through-hole for exposing a portion of the recording layer.

It is preferred that the third step comprise a step for etching the interlayer insulation film under conditions whereby a higher etching rate is obtained than in the conditions of etching the protective insulation film, and a step for etching the protective insulation film under conditions whereby a higher etching rate is obtained than in the conditions of etching the recording layer. Providing these steps makes it possible to more effectively reduce the amount of damage sustained by the recording layer during formation of the through-hole.

According to the present invention thus configured, the amount of heat released to the metal layer positioned above the recording layer is reduced in comparison with the conventional technique. The flow of the write current within the recording layer can also be further concentrated than in the conventional non-volatile memory element. The present invention thereby makes it possible to provide a non-volatile memory element having increased thermal efficiency, and to provide a method for manufacturing the same. Accordingly, not only can the write current be reduced, but the write speed can also be increased in comparison with the conventional technique. Since the protective insulation film is interposed between the interlayer insulation film and the upper surface of the recording layer, it becomes possible to reduce the amount of damage sustained by the recording layer during patterning of the recording layer and formation of the through-hole for exposing a portion of the recording layer.

### BRIEF DESCRIPTION OF THE DRAWINGS

The above and other objects, features and advantages of this invention will become more apparent by reference to the following detailed description of the invention taken in conjunction with the accompanying drawings, wherein:

FIG. 1 is a schematic sectional view of the structure of a non-volatile memory element according to a first preferred embodiment of the present invention;

FIG. 2 is a graph showing the method for controlling the phase state of the phase change material that includes a chalcogenide material;

FIG. 3 is a circuit diagram of a non-volatile semiconductor storage device having a matrix structure with n rows and m columns;

FIG. 4 is a sectional view showing an example of the structure of a memory cell MC that uses the non-volatile memory element shown in FIG. 1;

FIGS. 5 and 6 are schematic sectional views showing the sequence of steps for manufacturing the non-volatile memory element shown in FIG. 1;

FIG. 7 is a schematic sectional view showing the structure of a non-volatile memory element according to a second preferred embodiment of the present invention;

FIG. 8 is a schematic sectional view showing the sequence of steps for manufacturing the non-volatile memory element shown in FIG. 7;

FIG. 9 is a schematic plan view showing the structure of a non-volatile memory element according to a third preferred embodiment of the present invention;

FIG. 10 is a schematic sectional view along line A-A in FIG. 9;

FIG. 11 is a schematic plan view showing the structure of a non-volatile memory element according to a fourth preferred embodiment of the present invention;

FIG. 12 is a schematic sectional view along line D-D in FIG. 11;

FIG. 13 is a schematic plan view showing a modified structure of the non-volatile memory element shown in FIG. 11;

FIG. 14 is a schematic plan view showing another modified structure of the non-volatile memory element shown in FIG. 11;

FIG. 15 is a schematic sectional view showing the structure of a non-volatile memory element according to a fifth preferred embodiment of the present invention;

FIGS. 16 through 18 are schematic sectional views showing the sequence of steps for manufacturing the non-volatile memory element shown in FIG. 15;

FIG. 19 is a schematic plan view showing the structure of a non-volatile memory element according to the sixth preferred embodiment of the present invention;

FIG. 20 is a schematic sectional view along line E-E in FIG. 19;

FIG. 21 is a schematic sectional view along line F-F in FIG. 19;

FIGS. 22 through 25 are schematic sectional views showing the sequence of steps for manufacturing the non-volatile memory element shown in FIG. 19;

FIG. 26 is a schematic plan view showing the structure of a non-volatile memory element according to the seventh preferred embodiment of the present invention; and

FIGS. 27 through 31 are schematic sectional views showing the sequence of steps for manufacturing the non-volatile memory element shown in FIG. 26.

### DETAILED DESCRIPTION OF THE EMBODIMENTS

Preferred embodiments of the present invention will now be explained in detail with reference to the drawings.

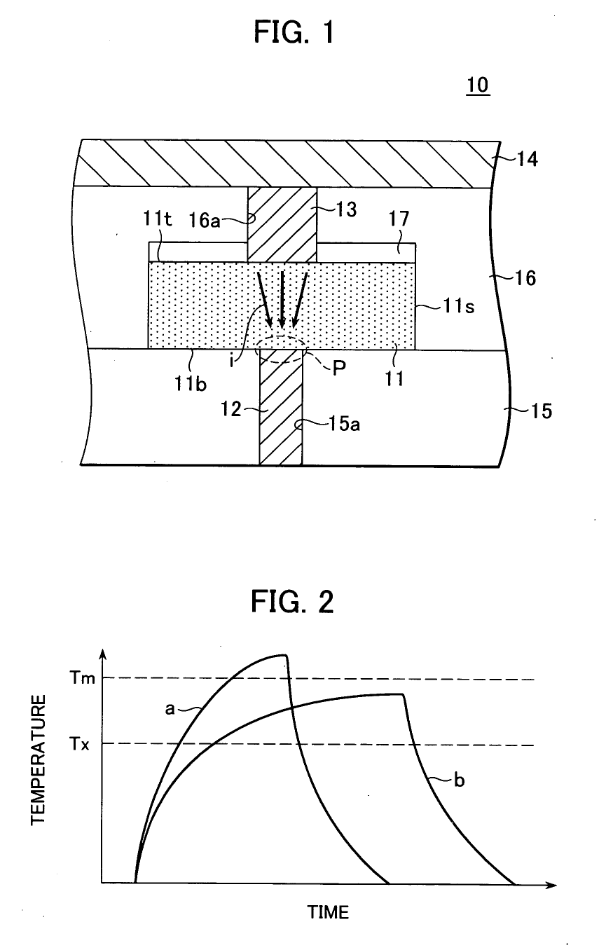

FIG. 1 is a schematic sectional view of the structure of the non-volatile memory element 10 according to a first preferred embodiment of the present invention.

As shown in the FIG. 1, the non-volatile memory element 10 according to the present invention is provided with a recording layer 11 that includes a phase change material, a lower electrode 12 provided in contact with the lower surface 11b of the recording layer 11, an upper electrode 13 provided in contact with the upper surface 11t of the recording layer 11, and a bit line 14 that is a metal layer provided on the upper electrode 13.

The lower electrode 12 is embedded in a through-hole 15a provided to a first interlayer insulation film 15. As shown in FIG. 1, the lower electrode 12 is in contact with the lower surface 11b of the recording layer 11, and is used as a heater plug during writing of data. In other words, the lower electrode becomes part of a heating body during writing of data. Therefore, the material used for the lower electrode 12 preferably has relatively high electrical resistance, and examples of such a material include metal suicides, metal nitrides, nitrides of metal silicides, and the like. This material is not subject to any particular limitation, but TiAlN, TiSiN, TiCN, and other materials can be preferred for use.

The recording layer 11 is provided so as to be embedded in a second interlayer insulation film 16 provided on a first interlayer insulation film 15. The side surface 11s of the recording layer 11 is thereby in contact with the second interlayer insulation film 16. A protective insulation film 17 is provided on the recording layer 11 so as to be embedded in the second interlayer insulation film 16, whereby a portion of the upper surface lit of the recording layer 11 is in contact with the protective insulation film 17. A through-hole 16a is provided to the second interlayer insulation film 16 and the protective insulation film 17, and the upper electrode 13 is provided inside the through-hole 16a. Specifically, in this structure, the upper electrode 13 is in contact with only a portion of the upper surface lit of the recording layer 11, and not the entire upper surface 11t of the recording layer 11, and the other portion of the upper surface 11t of the recording layer 11 is covered by the protective insulation film 17.

The recording layer 11 is composed of a phase change material. The phase change material constituting the recording layer 11 is not particularly limited insofar as the material assumes two or more phase states and has an electrical resistance that changes according to the phase state. A so-called chalcogenide material is preferably selected. A chalcogenide material is defined as an alloy that contains at least one or more elements selected from the group consisting of germanium (Ge), antimony (Sb), tellurium (Te), indium (In), selenium (Se), and the like. Examples include GaSb, InSb, InSe, Sb₂Te₃, GeTe, and other binary-based elements; Ge₂Sb₂Te₅, InSbTe, GaSeTe, SnSb₂Te₄, InSbGe, and other tertiary-based elements; and AgInSbTe, (GeSn)SbTe, GeSb(SeTe), Te₈₁Ge₁₅Sb₂S₂, and other quaternary-based elements.

A phase change material that includes a chalcogenide material may assume any phase state including an amorphous phase (non-crystalline phase) and a crystalline phase, with a relatively high-resistance state occurring in the amorphous phase, and a relatively low-resistance state occurring in the crystalline phase.

FIG. 2 is a graph showing the method for controlling the phase state of the phase change material that includes a chalcogenide material.

In order to place the phase change material that includes a chalcogenide material in the amorphous state, the material is cooled after being heated to a temperature equal to or higher than the melting point Tm, as indicated by the curve a in FIG. 2. In order to place the phase change material that includes a chalcogenide material in the crystalline state, the material is cooled after being heated to a temperature at or above the crystallization temperature Tx and lower than the melting point Tm. Heating may be performed by applying an electric current. The temperature during heating may be controlled according to the amount of applied current, i.e., the current application time or the amount of current per unit time.

When a write current flows to the recording layer 11, the area near where the recording layer 11 and the lower electrode 12 are in contact with each other becomes a heat generation region P. In other words, the phase state of the chalcogenide material in the vicinity of the heat generation region P can be changed by the flow of a write current to the recording layer 11. The electrical resistance between the bit line 14 and the lower electrode 12 is thereby changed.

The distance between the heat generation region P and the upper electrode 13 that becomes the route of heat discharge can be increased by increasing the thickness of the recording layer 11, and the reduction in thermal efficiency caused by the release of heat towards the upper electrode 13 can thereby be prevented. However, when the thickness of the recording layer 11 is too large, not only does it take more time to form the film, but thermal efficiency also decreases as a result of the increase in the volume of the heating body itself. Particularly during the phase change from a high-resistance state to a low-resistance state, a stronger electric field is required to induce this change. Specifically, using a high voltage to induce a phase change is not compatible with a low-voltage device. Accordingly, the thickness of the recording layer 11 must be defined with consideration for the factors described above. A film thickness of 200 nm or less is preferred, and a film thickness of 30 nm to 100 nm is more preferred.

Reducing the planar size of the recording layer 11 also reduces the volume of the heating body, making it possible to increase thermal efficiency. However, having a recording layer 11 with a small planar size decreases the distance between the heat generation region P and the side surface 11s that is easily penetrated by oxygen and other impurities. As a result, the recording layer 11 or lower electrode 12 in the vicinity of the heat generation region P becomes more prone to deteriorate. When the planar size of the recording layer 11 is decreased too much; e.g., when the planar size of the recording layer 11 is reduced to about the same size as the upper electrode 13, misalignment that unavoidably occurs during manufacturing makes it difficult to properly form the through-hole 16a in the upper surface 11t portion of the recording layer 11, resulting in possible instability of contact between the recording layer 11 and the upper electrode 13. The planar size of the recording layer 11 must therefore be defined with consideration for the factors described above.

The upper electrode 13 is an electrode that forms a pair with the lower electrode 12. The material used to form the upper electrode 13 is preferably provided with a relatively low coefficient of thermal conductivity in order to inhibit the escape of heat generated by electric current flow. Specifically, TiAlN, TiSiN, TiCN, and other materials may be preferably used, the same as for the lower electrode 12.

The bit line 14 is provided on the second interlayer insulation film 16, and is in contact with the upper surface of the upper electrode 13. A metal material having low electrical resistance is selected for use as the material for forming the bit line 14. For example, aluminum (Al), titanium (Ti), tungsten (W), or an alloy thereof, or a nitride, silicide, or other compound of these metals may be preferred for use. Specific substances may include W, WN, TiN, and the like.

A silicon oxide film, a silicon nitride film, or the like may be used as the material for forming the first and second interlayer insulation films 15, 16 or the protective insulation film 17, and it is preferred that at least the second interlayer insulation film 16 and the protective insulation film 17 be formed from different materials. For example, the second interlayer insulation film 16 may be composed of a silicon oxide film, and the protective insulation film 17 may be composed of a silicon nitride film. It is preferred that the thickness of the protective insulation film 17 be set adequately low, i.e., 30 to 150 nm.

The non-volatile memory element 10 having this type of structure may be formed on a semiconductor substrate, and an electrically rewritable non-volatile semiconductor storage device can be constructed by arranging non-volatile memory elements in a matrix.

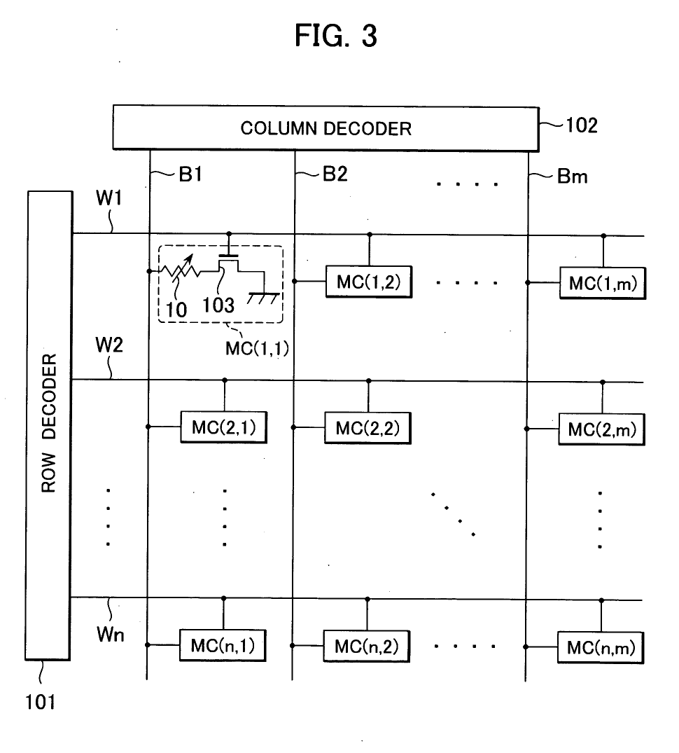

FIG. 3 is a circuit diagram of a non-volatile semiconductor storage device having a matrix structure with n rows and m columns.

The non-volatile semiconductor storage device shown in FIG. 3 is provided with n word lines W1-Wn, m bit lines B1-Bm, and memory cells MC(1, 1)-MC(n, m) disposed at the intersections of the word lines and the bit lines. The word lines W1-Wn are connected to a row decoder 101, and the bit lines B1-Bm are connected to a column decoder 102. The memory cells MC are composed of a non-volatile memory element 10 and a transistor 103 connected in series between a ground and the corresponding bit line. The control terminal of the transistor 103 is connected to the corresponding word line.

The non-volatile memory element 10 has the structure described with reference to FIG. 1. The lower electrode 12 of the non-volatile memory element 10 is therefore connected to the corresponding transistor 103.

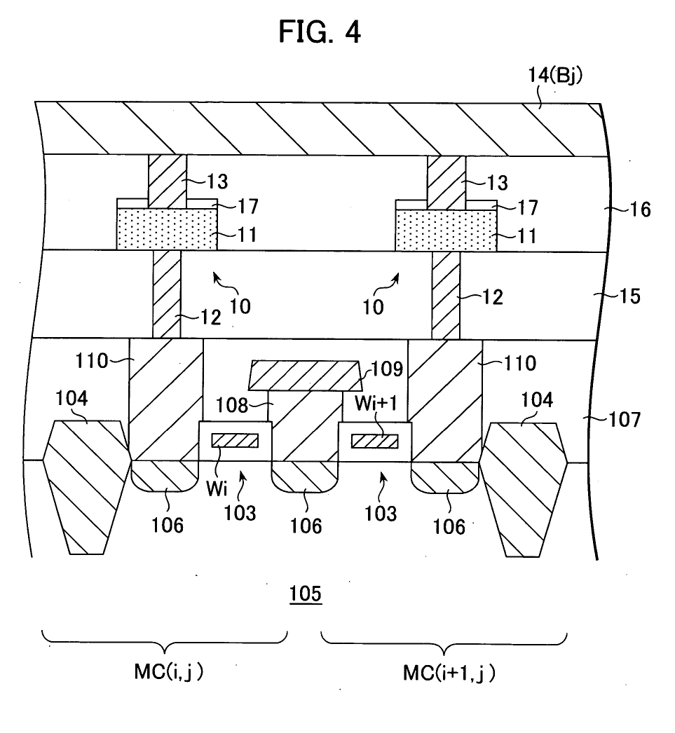

FIG. 4 is a sectional view showing an example of the structure of a memory cell MC that uses the non-volatile memory element 10. FIG. 4 shows two memory cells MC(i, j), MC(i+1, j) that share the same corresponding bit line Bj.

As shown in FIG. 4, the gates of the transistors 103 are connected to word lines Wi, Wi+1. Three diffusion regions 106 are formed in a single active region 105 partitioned by element separation regions 104, whereby two transistors 103 are formed in a single active region 105. These two transistors 103 share the same source, which is connected to ground wiring 109 via a contact plug 108 provided to the interlayer insulation film 107. The drains of the transistors 103 are connected to the lower electrode 12 of the corresponding non-volatile memory element 10 via contact plugs 110. The two non-volatile memory elements 10 share the same bit line Bj.

The non-volatile semiconductor storage device having this type of configuration can perform writing and reading of data by activating any of the word lines W1-Wn through the use of the row decoder 101, and allowing a current to flow to at least one of the bit lines B1-Bm in this state. In other words, in a memory cell in which the corresponding word line is activated, the transistor 103 is ON, and the corresponding bit line is then connected to the ground via the non-volatile memory element 10. Accordingly, by allowing a write current to flow to the bit line selected by a prescribed column decoder 102 in this state, a phase change can be effected in the recording layer 11 included in the non-volatile memory element 10.

Specifically, by allowing a prescribed amount of current to flow, the phase change material constituting the recording layer 11 is placed in the amorphous phase by heating the phase change material to a temperature equal to or higher than the melting point Tm shown in FIG. 2, and then rapidly interrupting the current to cause rapid cooling. By allowing an amount of current to flow that is smaller than the abovementioned prescribed amount, the phase change material constituting the recording layer 11 is placed in the crystalline phase by heating the phase change material to a temperature equal to or higher than the crystallization temperature Tx and less than the melting point Tm shown in FIG. 2, and then gradually reducing the current to cause gradual cooling in order to facilitate crystal growth.

Also in the case of reading data, any one of the word lines W1-Wn is activated by the row decoder 101, and while in this state, a read current is allowed to flow to at least one of the bit lines B1-Bm. Since the resistance value is high for a memory cell in which the recording layer 11 is in the amorphous phase, and the resistance value is low for a memory cell in which the recording layer 11 is in the crystalline phase, the phase state of the recording layer 11 can be ascertained by detecting these values using a sense amplifier (not shown).

The phase state of the recording layer 11 can be correlated with a stored logical value. For example, defining an amorphous phase state as “0” and a crystalline phase state as “1” makes it possible for a single memory cell to retain 1-bit data. The crystallization ratio can also be controlled in multi-stage or linear fashion by adjusting the time for which the recording layer 11 is maintained at the temperature equal to or higher than the crystallization temperature Tx and less than the melting point Tm when a change occurs from the amorphous phase to the crystalline phase. Performing multi-stage control of the mixture ratio of amorphous states and crystalline states by this type of method makes it possible for 2-bit or higher order data to be stored in a single memory cell. Furthermore, performing linear control of the mixture ratio of amorphous states and crystalline states makes it possible to store analog values.

The method for manufacturing the non-volatile memory element 10 according to the present embodiment will next be described.

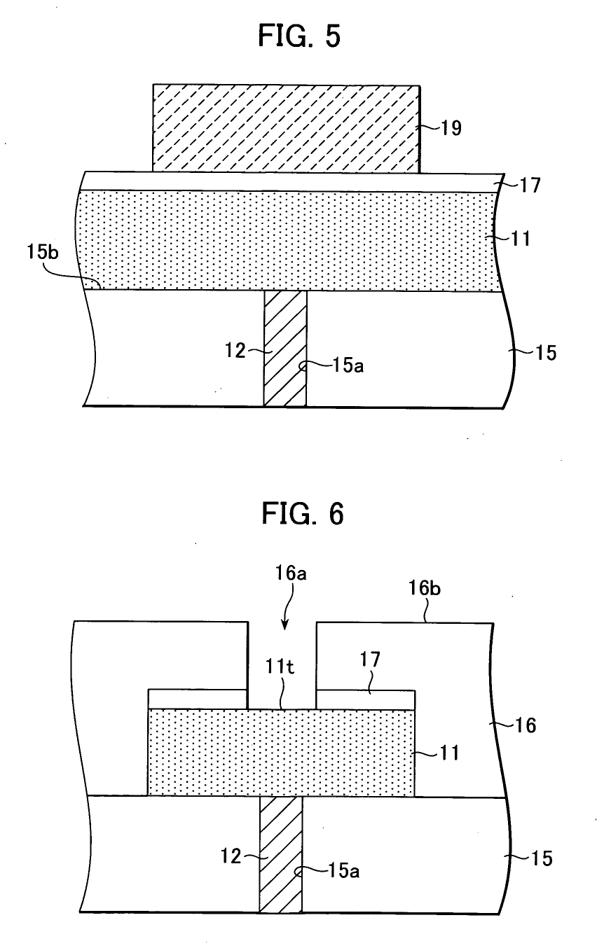

FIGS. 5 and 6 are schematic sectional views showing the sequence of steps for manufacturing the non-volatile memory element 10.

First, as shown in FIG. 5, the first interlayer insulation film 15 is formed, and then the through-hole 15a is formed in this first interlayer insulation film 15. The lower electrode 12 is subsequently formed on the first interlayer insulation film 15 so that the through-hole 15a is completely embedded, and the lower electrode 12 is polished until the upper surface 15b of the first interlayer insulation film 15 is exposed. Polishing is preferably performed using a CMP method. A state is thereby attained in which the lower electrode 12 is embedded in the through-hole 15a. A common CVD method may be used to form the first interlayer insulation film 15. Common photolithography methods and dry etching methods may be used to form the through-hole 15a.

A recording layer 11 composed of a chalcogenide material, and a protective insulation film 17 are then formed in sequence on the first interlayer insulation film 15. The method for forming the recording layer 11 is not subject to any particular limitation, but a sputtering method or a CVD method may be used. A method that does as little damage as possible to the chalcogenide material included in the recording layer 11 is preferably selected for use in forming the protective insulation film 17. For example, the protective insulation film 17 is preferably formed by depositing a silicon nitride film using a plasma CVD method. A photoresist 19 is then formed in a prescribed region of the protective insulation film 17 using a common photolithography method.

The protective insulation film 17 and the recording layer 11 are then patterned using the photoresist 19 as a mask, and the unnecessary portions of the protective insulation film 17 and recording layer 11 are removed. The photoresist 19 is then removed by ashing. Since the upper surface lit of the recording layer 11 is covered by the protective insulation film 17 at this time, the recording layer 11 can be prevented from sustaining damage from the ashing process.

As shown in FIG. 6, the second interlayer insulation film 16 for covering the recording layer 11 and protective insulation film 17 is then formed. A common CVD method may also be used to form the second interlayer insulation film 16. A through-hole 16a is then formed in the second interlayer insulation film 16 and protective insulation film 17, thereby exposing a portion of the upper surface 11t of the recording layer 11. The other portion of the upper surface 11t of the recording layer 11 remains covered by the protective insulation film 17. Common photolithography methods and dry etching methods may be used to form the through-hole 16a.

In forming the through-hole 16a, it is preferred that the second interlayer insulation film 16 first be etched (first etching) under conditions that give a high selection ratio with respect to the protective insulation film 17, and then that the protective insulation film 17 be etched (second etching) under conditions that give a high selection ratio with respect to the recording layer 11. By so doing, the recording layer 11 is no longer exposed to the etching environment during the first etching in which a larger amount of etching takes place. Although the recording layer 11 is somewhat exposed to the etching environment during the second etching, the protective insulation film 17 has a small film thickness, and etching can be controlled with high precision. Damage to the recording layer 11 can therefore be minimized.

Then, as shown in FIG. 1, the upper electrode 13 is formed on the second interlayer insulation film 16 so that the through-hole 16a is completely embedded, and the upper electrode 13 is then polished until the upper surface 16b of the second interlayer insulation film 16 is exposed. Polishing is preferably performed using a CMP method. A state is thereby attained in which the upper electrode 13 is embedded in the through-hole 16a, as shown in FIG. 1. The upper electrode 13 is preferably formed by a film formation method that yields excellent step coverage, i.e., a CVD method. The upper electrode 13 can thereby be completely embedded in the through-hole 16a.

By forming a bit line 14 on the second interlayer insulation film 16 and performing patterning in a prescribed shape, the non-volatile memory element 10 according to the present embodiment is completed.

In the non-volatile memory element 10 according to the present embodiment thus configured, the entire upper surface 11t of the recording layer 11 is not in contact with the upper electrode 13, but only a portion thereof is in contact with the upper electrode 13, and the other portion is in contact with the protective insulation film 17, which has a low coefficient of thermal conductivity. Since the size of the area of contact between the recording layer 11 and the upper electrode 13 is thereby reduced, the amount of heat released to the side of the upper electrode 13 decreases. Since the volume of the upper electrode 13 also decreases, the heat capacity of the upper electrode 13 decreases as well. The protective insulation film 17 is not electrically conductive, and therefore also has a low coefficient of thermal conductivity, and the amount of heat released via the protective insulation film 17 is relatively small.

The size of the area of contact between the recording layer 11 and the upper electrode 13 is small, and the write current i flowing to the recording layer 11 is therefore distributed in a concentrated manner, as shown in FIG. 1. As a result, the write current i efficiently flows into the heat generation region P.

Higher thermal efficiency in comparison with the conventional technique can therefore be obtained in the non-volatile memory element 10 according to the present embodiment. As a result, it is possible not only to decrease the write current, but also to increase the write speed.

Furthermore, since the upper surface 11t of the recording layer 11 is covered by the protective insulation film 17 as shown in FIG. 5 during patterning of the recording layer 11 in the non-volatile memory element 10 according to the present embodiment, it is also possible to prevent damage to the recording layer 11 during ashing of the photoresist 19. It also becomes possible to minimize damage to the recording layer 11 when the through-hole 16a is formed.

The non-volatile memory element 20 according to a second preferred embodiment of the present invention will next be described.

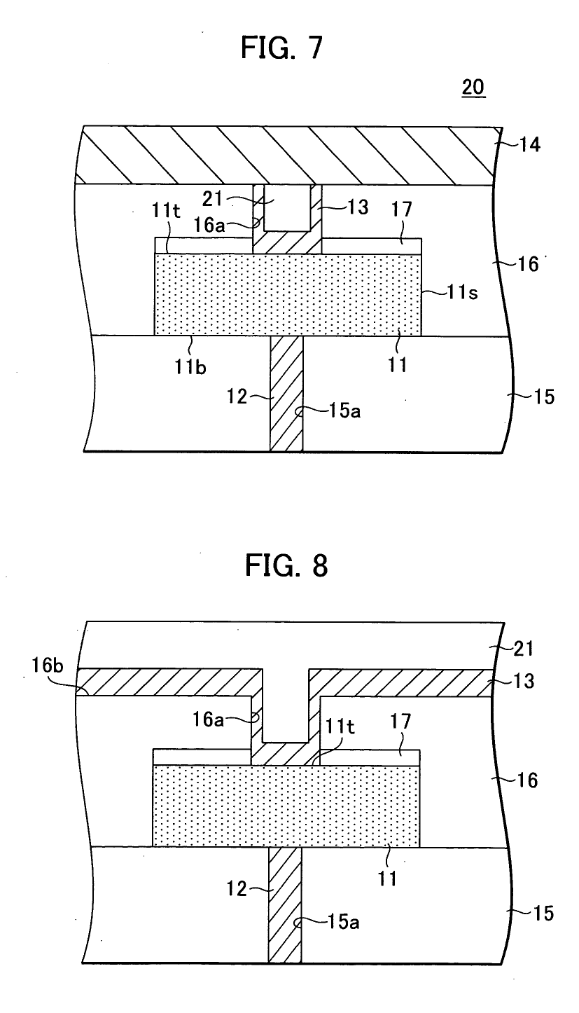

FIG. 7 is a schematic sectional view showing the structure of the non-volatile memory element 20 according to a second preferred embodiment of the present invention.

As shown in FIG. 7, the non-volatile memory element 20 according to the present embodiment differs from the non-volatile memory element 10 of the abovementioned embodiment in that the upper electrode 13 is formed only in a wall surface portion of the through-hole 16a rather than in the entire through-hole 16a, and a buried member 21 is filled into the region surrounded by the upper electrode 13 in the inside of the through-hole 16a. Since other aspects of this configuration are the same as in the non-volatile memory element 10 according to the abovementioned embodiment, the same reference symbols are used to indicate the same elements, and descriptions of these elements are not repeated.

The buried member 21 is not subject to any particular limitations insofar as it is composed of a material having a lower coefficient of thermal conductivity than the upper electrode 13. Silicon oxide, silicon nitride, or another insulating material is preferably used. Although this configuration is not particularly limited, the buried member 21 is not in contact with the recording layer 11, and the entire bottom portion of the through-hole 16a is covered by the upper electrode 13.

This type of configuration makes it possible to even further decrease the amount of heat released to the side of the upper electrode 13, since the heat capacity of the upper electrode 13 decreases. A level of thermal efficiency higher than that of the first embodiment can thereby be obtained, and it becomes possible not only to further decrease the write current, but also to further increase the write speed.

The method for manufacturing the non-volatile memory element 20 according to the present embodiment will next be described.

FIG. 8 is a schematic sectional view showing the sequence of steps for manufacturing the non-volatile memory element 20.

By performing the same steps as those described using FIGS. 5 and 6, a through-hole 16a is formed in the second interlayer insulation film 16, after which the upper electrode 13 is formed with a thickness sufficient to fill a portion of the through-hole 16a as shown in FIG. 8. A buried member 21 is then formed with a thickness sufficient to entirely fill the through-hole 16a. The upper electrode 13 is preferably formed by a film formation method having excellent directional characteristics so that the upper electrode 13 is reliably deposited in the bottom portion of the through-hole 16a, i.e., on the upper surface 11t of the recording layer 11. A directional sputtering method, for example, is preferred as the method used to form the upper electrode 13. The buried member 21 is preferably formed by a film formation method that yields excellent step coverage, i.e., a CVD method.

The buried member 21 and the upper electrode 13 are polished by a CMP method or the like until the upper surface 16b of the second interlayer insulation film 16 is exposed. A state is thereby attained in which the upper electrode 13 and the buried member 21 are embedded in the through-hole 16a. By forming a bit line 14 on the second interlayer insulation film 16 and performing patterning in a prescribed shape, the non-volatile memory element 20 according to the present embodiment is completed.

Fabricating the non-volatile memory element 20 according to this type of method makes it possible to obtain thermal efficiency that is higher than that of the first embodiment while keeping the increase in the number of steps to a minimum.

The non-volatile memory element 30 according to a third preferred embodiment of the present invention will next be described.

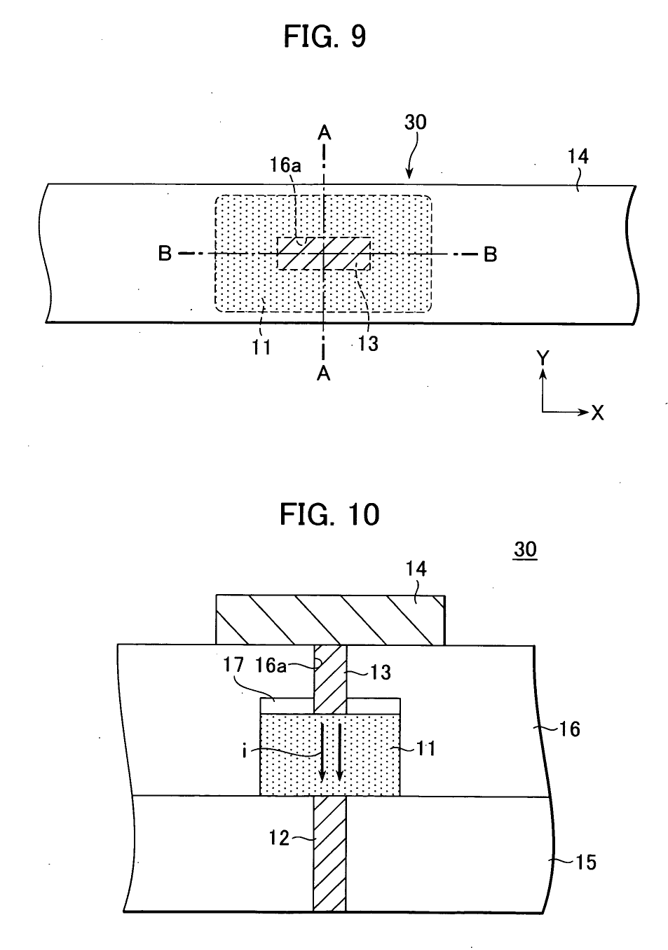

FIG. 9 is a schematic plan view showing the structure of the non-volatile memory element 30 according to a third preferred embodiment of the present invention. FIG. 10 is a schematic sectional view along line A-A in FIG. 9. The schematic sectional view along line B-B in FIG. 9 is the same as FIG. 1.

As shown in FIGS. 9 and 10, the non-volatile memory element 30 according to the present embodiment differs from the non-volatile memory element 10 of the first embodiment in that the through-hole 16a in which the upper electrode 13 is embedded has a rectangular shape that is long in the X-direction, which is the extension direction of the bit line 14, and short in the Y-direction, which is the direction orthogonal to the extension direction of the bit line 14. Since other aspects of this configuration are the same as in the non-volatile memory element 10 according to the first embodiment, the same reference symbols are used to indicate the same elements, and descriptions of these elements are not repeated.

When the through-hole 16a for embedding the upper electrode 13 has a rectangular planar shape as in the present embodiment, the write current i is more concentrated in the Y-direction, as shown in FIG. 10. This makes it possible to feed the write current i to the heat generation region P more efficiently. 5 In the present embodiment, since the diameter of the through-hole 16a is reduced in the direction (Y-direction) orthogonal to the extension direction of the bit line 14, even when misalignment occurs during manufacturing, the area of contact between the upper electrode 13 and the bit line 14 is kept constant. Stable characteristics can therefore be obtained.

The non-volatile memory element 40 according to a fourth preferred embodiment of the present invention will next be described.

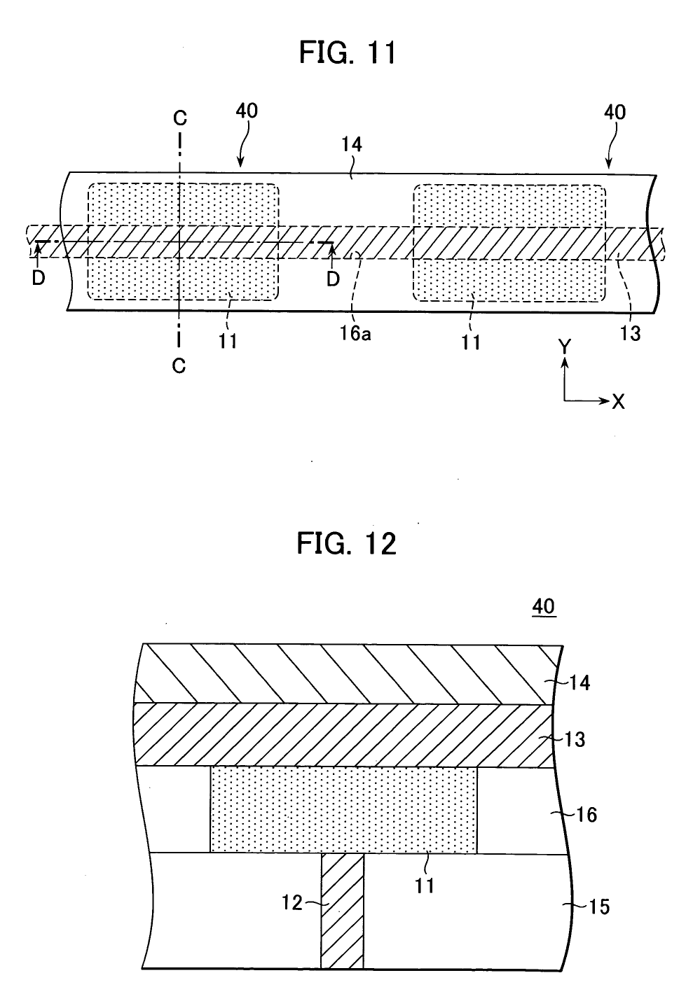

FIG. 11 is a schematic plan view showing the structure of the non-volatile memory element 40 according to a fourth preferred embodiment of the present invention, and FIG. 12 is a schematic sectional view along line D-D in FIG. 11. The schematic sectional view along line C-C in FIG. 11 is the same as FIG. 10.

As shown in FIGS. 11 and 12, the non-volatile memory element 40 according to the present embodiment differs from the non-volatile memory element 30 of the third embodiment described above in that the through-hole 16a in which the upper electrode 13 is embedded is continuously provided to a plurality of non-volatile memory elements 40 that share the same bit line 14. Since other aspects of this configuration are the same as in the non-volatile memory element 30 according to the third embodiment, the same reference symbols are used to indicate the same elements, and descriptions of these elements are not repeated.

The write current i is also more concentrated in the Y-direction in the present embodiment, as shown in FIG. 10. This makes it possible to feed the write current i to the heat generation region P more efficiently. In the present embodiment, since the upper electrode 13 is continuously provided to a plurality of non-volatile memory elements 40 that share the same bit line 14, the write current i is somewhat scattered in the X-direction, but the upper electrode 13 acts as auxiliary wiring for the bit line 14, making it possible to reduce the wiring resistance of the bit line as a whole.

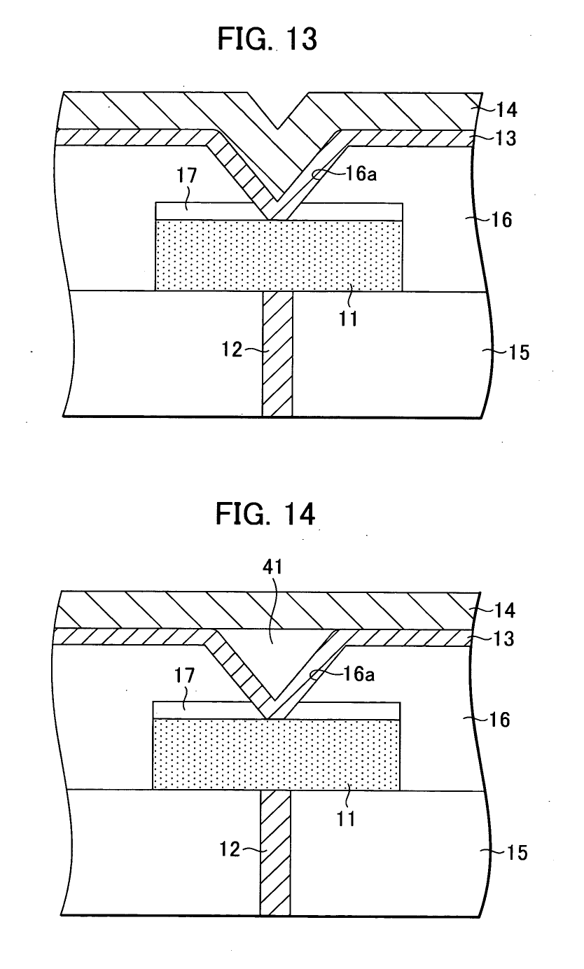

As a modified example of the present embodiment, the through-hole 16a in which the upper electrode 13 is embedded may also have a tapered shape as shown in FIG. 13. In this case, a through-hole 16a is provided separately to each non-volatile memory element. Adopting this type of configuration allows the write current i to concentrated not only in the Y-direction, but also in the X-direction, and hence makes it possible to further enhance thermal efficiency.

As another modified example of the present embodiment, the through-hole 16a may be tapered, and the remaining space in the through-hole 16a in which the upper electrode 13 is embedded may be filled by a buried member 41. The buried member 41 is not subject to any particular limitations insofar as it is composed of a material having a lower coefficient of thermal conductivity than the upper electrode 13. Silicon oxide, silicon nitride, or another insulating material is preferably used. When this type of configuration is adopted, the tapered shape enlarges the space in the through-hole 16a, but not having the metal layer bit line 14 formed inside the through-hole 16a makes it possible to decrease the amount of heat released to the side of the bit line 14.

The non-volatile memory element 50 according to a preferred fifth embodiment of the present invention will next be described.

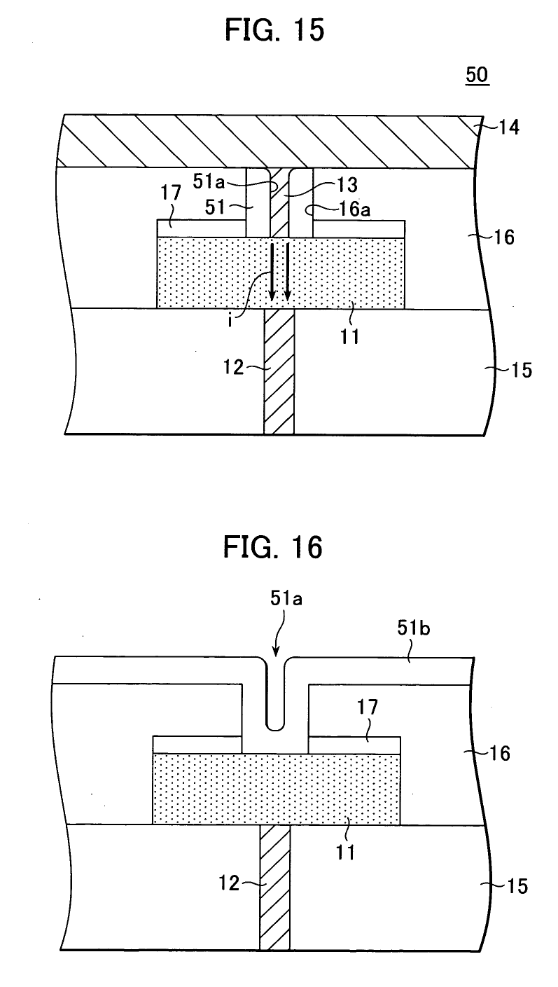

FIG. 15 is a schematic sectional view showing the structure of the non-volatile memory element 50 according to a fifth preferred embodiment of the present invention.

As shown in FIG. 15, the non-volatile memory element 50 according to the present embodiment differs from the non-volatile memory element 10 according to the first embodiment in that sidewalls 51 are formed in the inner wall of the through-hole 16a, and the upper electrode 13 is provided in the region 51a surrounded by the sidewalls 51. Since other aspects of this configuration are the same as in the non-volatile memory element 10 according to the first embodiment, the same reference symbols are used to indicate the same elements, and descriptions of these elements are not repeated.

The sidewalls 51 are not subject to any particular limitations insofar as they are composed of a material having a lower coefficient of thermal conductivity than the upper electrode 13. Silicon oxide, silicon nitride, or another insulating material is preferably used, the same as for the buried member 21 shown in FIG. 7. The sidewalls 51 are provided along the inner wall of the through-hole 16a, and the diameter of the region 51a surrounded by the sidewalls 51 is therefore significantly smaller than the diameter of the through-hole 16a. The size of the area of contact between the recording layer 11 and the upper electrode 13 is thereby reduced even further. It therefore becomes possible to even further reduce the heat capacity of the upper electrode 13, and to even further concentrate the write current i.

The method for manufacturing the non-volatile memory element 50 according to the present embodiment will next be described.

FIGS. 16 through 18 are schematic sectional views showing the sequence of steps for manufacturing the non-volatile memory element 50.

First, by performing the same steps as those described using FIGS. 5 and 6, a through-hole 16a is formed in the second interlayer insulation film 16, after which a sidewall insulation film 51b is formed with a thickness sufficient to fill a portion of the through-hole 16a as shown in FIG. 16. The entire inner wall of the through-hole 16a is thereby covered by the sidewall insulation film 51b, and a region 51a as a cavity is formed in the portion at the substantial center in the planar direction of the through-hole 16a. The sidewall insulation film 51b is preferably formed by a film formation method that yields excellent step coverage, i.e., a CVD method.

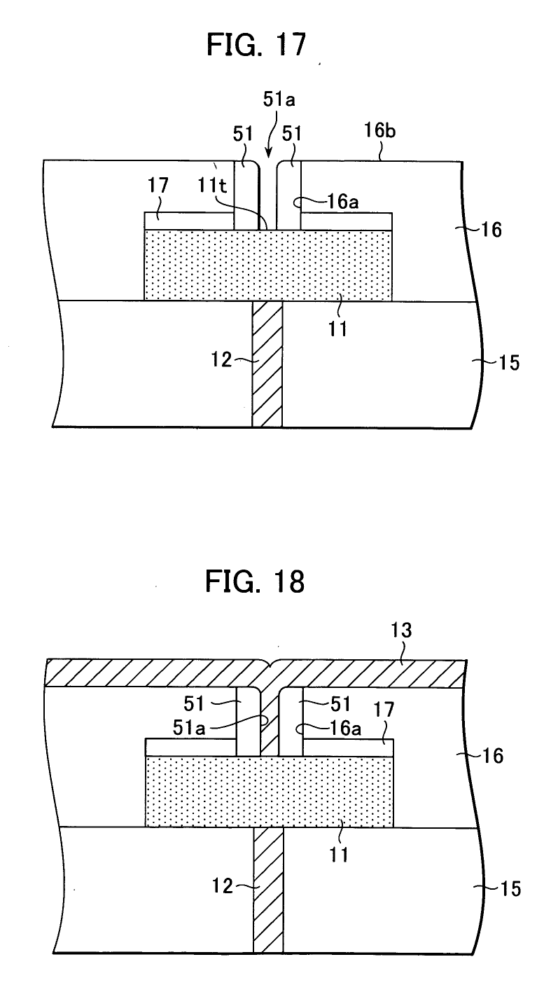

The sidewall insulation film 51b is then etched back as shown in FIG. 17. The sidewalls 51 thereby remain inside the through-hole 16a, and the upper surface 11t of the recording layer 11 is exposed in the region not covered by the sidewalls 51. There is no need to expose the upper surface 16b of the second interlayer insulation film 16 in the etching back of the sidewall insulation film 51b, and etching back may be completed while the sidewall insulation film 51b remains on the upper surface 16b of the second interlayer insulation film 16 insofar as the upper surface 11t of the recording layer 11 is exposed.

An upper electrode 13 is then formed on the entire surface so as to fill in the region 51a surrounded by the sidewalls 51, as shown in FIG. 18. The upper electrode 13 is thereby placed in contact with the upper surface 11t of the recording layer 11. The upper electrode 13 is preferably formed by a film formation method having excellent directional characteristics so that the upper electrode 13 is reliably deposited on the upper surface 11t of the recording layer 11. A directional sputtering method, an ALD (Atomic Layer Deposition) method, or a combination of these methods with a CVD method, for example, is preferred as the method used to form the upper electrode 13.

The upper electrode 13 is then polished by a CMP method or the like until the upper surface 16b (or the remaining sidewall insulation film 51b) of the second interlayer insulation film 16 is exposed. A state is thereby attained in which the upper electrode 13 is embedded in the region 51a surrounded by the sidewalls 51. The non-volatile 5 memory element 50 according to the present embodiment is then completed by forming the bit line 14 on the second interlayer insulation film 16 and performing patterning in a prescribed shape, as shown in FIG. 15.

By fabricating the non-volatile memory element 50 according to this type of method, the diameter of the upper electrode 13 can be made smaller than the lithography resolution. As described above, it therefore becomes possible to even further reduce the heat capacity of the upper electrode 13, and to even further concentrate the write current i.

The non-volatile memory element 60 according to a sixth preferred embodiment of the present invention will next be described.

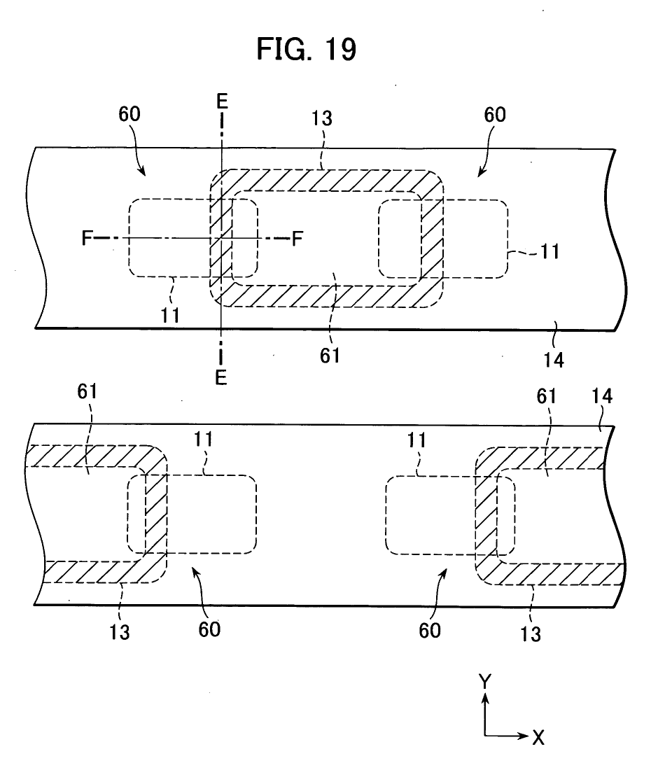

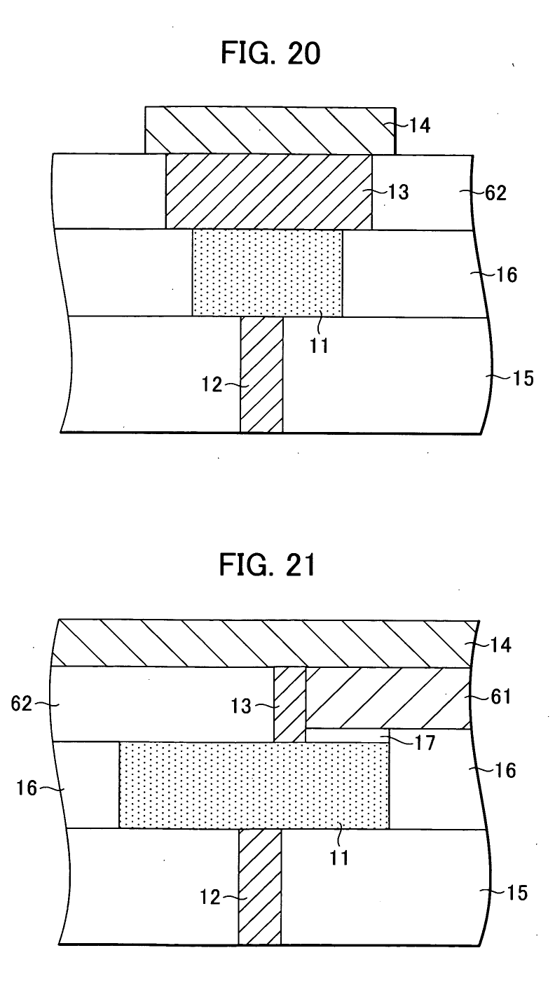

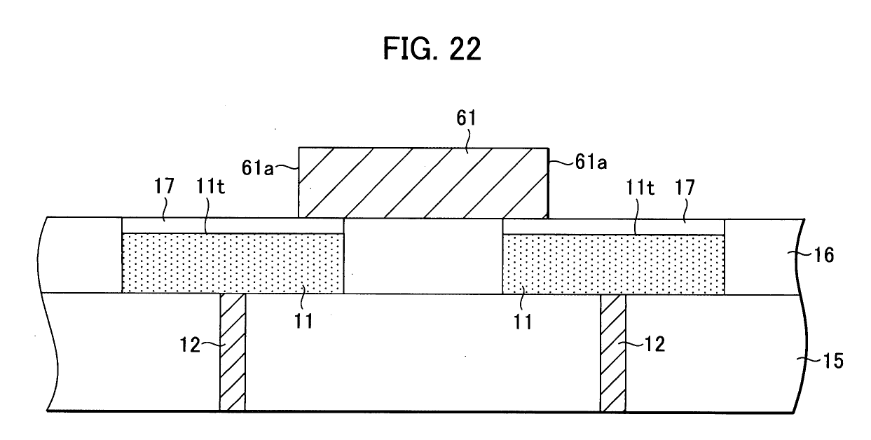

FIG. 19 is a schematic plan view showing the structure of the non-volatile memory element 60 according to the sixth preferred embodiment of the present invention. FIG. 20 is a schematic sectional view along line E-E in FIG. 19, and FIG. 21 is a schematic sectional view along line F-F in FIG. 19.

As shown in FIG. 19, in the non-volatile memory element 60 according to the present embodiment, the planar shape of the upper electrode 13 is ring-shaped, and a single upper electrode 13 is provided for two adjacent non-volatile memory elements 60 that are connected to the same bit line 14. As shown in FIGS. 19 and 21, a sidewall-forming insulation film 61 is provided to the region enclosed by the ring-shaped upper electrode 13. As shown in FIGS. 20 and 21, a third interlayer insulation film 62 is provided to the region outside the ring-shaped upper electrode 13. The same reference symbols are used to indicate elements that are the same as those of the non-volatile memory elements of the embodiments described above, and descriptions of these elements are not repeated.

In the present embodiment, the two non-volatile memory elements 60 connected to adjacent bit lines 14 are arranged along the Y-direction orthogonal to the extension direction of the bit lines 14. Therefore, the upper electrodes 13 provided so as to correspond to adjacent bit lines 14 are offset in the X-direction as shown in FIG. 19 so that the ring-shaped upper electrodes 13 do not interfere between the adjacent bit lines 14.

The method for manufacturing the non-volatile memory element 60 according to the present embodiment will next be described.

FIGS. 22 through 25 are schematic sectional views showing the sequence of steps for manufacturing the non-volatile memory element 60.

First, as shown in FIG. 22, the recording layer 11 covered by the protective insulation film 17 is patterned, after which a second interlayer insulation film 16 is formed for covering the recording layer 11 and the protective insulation film 17. The second interlayer insulation film 16 is then polished by a CMP method or the like to flatten the surface thereof, and the sidewall-forming insulation film 61 is patterned after being formed on the entire surface of the second interlayer insulation film 16. At this time, the sidewall-forming insulation film 61 is patterned so that the ends 61a in the planar direction traverse the upper surfaces 11t of the two recording layers 11. Selecting different insulating materials in advance as the materials for forming the second interlayer insulation film 16 and the protective insulation film 17 makes it possible to use the protective insulation film 17 as a stopper when the second interlayer insulation film 16 is polished by a CMP method.

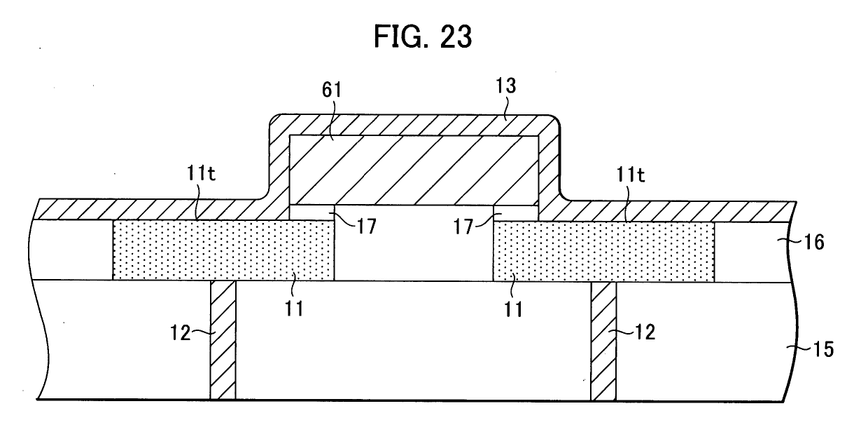

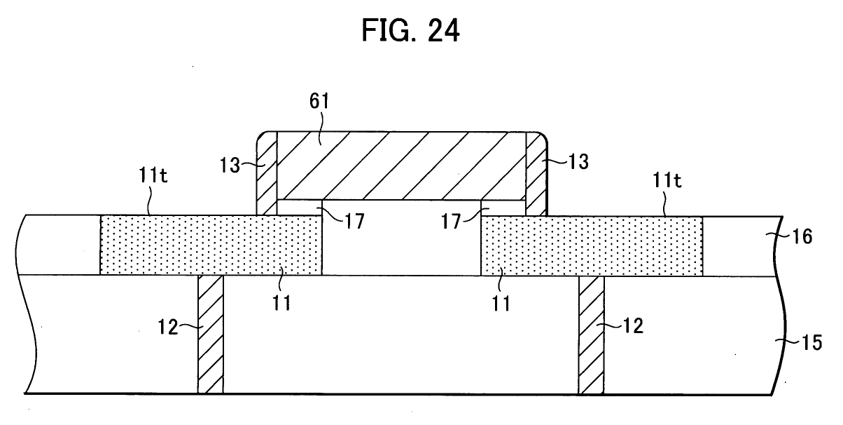

As shown in FIG. 23, the protective insulation film 17 is then etched using as a mask the sidewall-forming insulation film 61, exposing the regions of the upper surfaces 11t of the recording layers 11 that are not covered by the sidewall-forming insulation film 61. The second interlayer insulation film 16 may also be etched simultaneously with the protective insulation film 17 at this time. After the upper surfaces 11t of the recording layers 11 are exposed in this manner, the upper electrode 13 is formed over the entire surface. A state is thereby attained in which the exposed upper surfaces 11t of the recording layers 11 are in contact with the upper electrode 13.

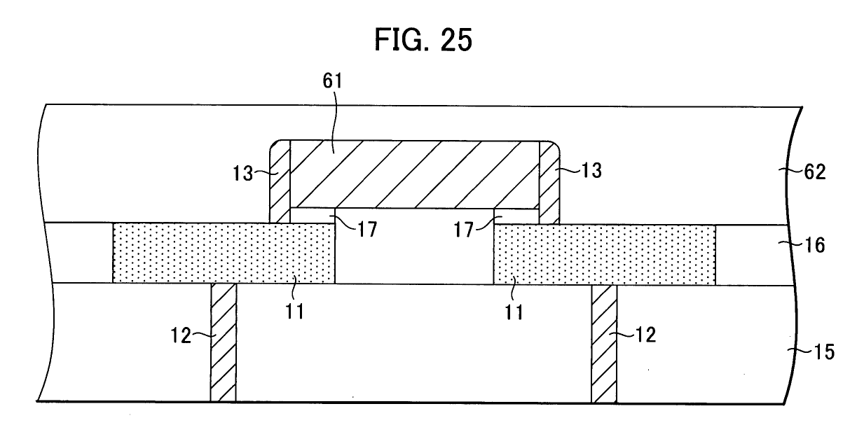

As shown in FIG. 24, the upper electrode 13 is then etched back, and the upper surfaces 11t of the recording layers 11 are again exposed. A state is thereby attained in which the portions of the upper electrode 13 formed in the plane essentially parallel to the substrate are removed, and the upper electrode 13 remains only on the wall surface portions of the sidewall-forming insulation film 61. The planar shape of the upper electrode 13 therefore becomes ring-shaped.

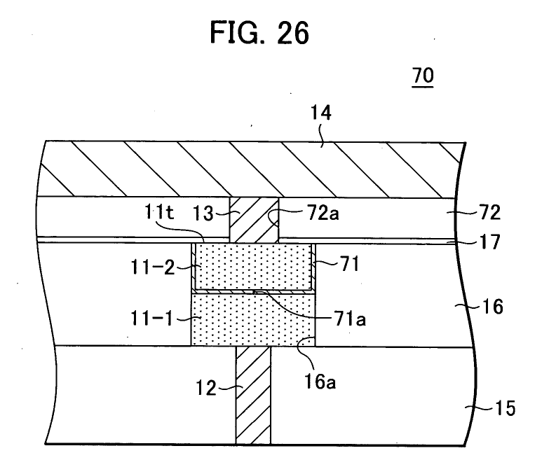

A third interlayer insulation film 62 for covering the sidewall-forming insulation film 61 is then formed as shown in FIG. 25. The third interlayer insulation film 62 is then polished by a CMP method or the like until the upper electrode 13 is exposed, after which a bit line 14 is formed on the third interlayer insulation film 62 and the sidewall-forming insulation film 61, and a pattern having a prescribed shape is formed in the bit line 14 to complete the non-volatile memory element 60 according to the present embodiment.

In the non-volatile memory element 60 fabricated according to this type of method, the width of the ring-shaped upper electrode 13 is dependent on the film thickness obtained during film formation, and the width of the upper electrode 13 can therefore be made smaller than the lithography resolution. It therefore becomes possible to even further reduce the heat capacity of the upper electrode 13, and to even further concentrate the write current i.

The non-volatile memory element 70 according to a seventh preferred embodiment of the present invention will next be described.

FIG. 26 is a schematic plan view showing the structure of the non-volatile memory element 70 according to the seventh preferred embodiment of the present invention.

As shown in FIG. 26, the non-volatile memory element 70 according to the present embodiment has a structure in which two recording layers 11-1, 11-2 are embedded inside a through-hole 16a, and a thin-film insulating layer 71 is provided between the recording layers 11-1, 11-2. A protective insulation film 17 and a third interlayer insulation film 72 are provided on the second interlayer insulation film 16, and the upper electrode 13 is embedded inside a through-hole 72a provided to the protective insulation film 17 and third interlayer insulation film 72. The upper electrode 13 is in contact only with a portion of the upper surface lit of the recording layer 11-2, and the other portion is covered by the protective insulation film 17. The same reference symbols are used to indicate elements that are the same as those of the non-volatile memory elements of the embodiments described above, and descriptions of these elements are not repeated.

The thin-film insulating layer 71 is a layer in which a pinhole 71a is formed by inducing dielectric breakdown. No particular limitations are imposed on the material used to form the thin-film insulating layer 71. Si₃N₄, SiO₂, Al₂O₃, or another insulating material may be used. The thickness of the thin-film insulating layer 71 must be set in a range that allows dielectric breakdown to be caused by an applicable voltage. The thickness of the thin-film insulating layer 71 must therefore be adequately small.

The pinhole 71a is formed by applying a high voltage across the lower electrode 12 and upper electrode 13 to induce dielectric breakdown in the thin-film insulating layer 71. Since the diameter of the pinhole 71a formed by dielectric breakdown is extremely small in comparison with the diameter of a through-hole or the like that can be formed by lithography, the current path concentrates in the pinhole 71a when a current is allowed to flow in the non-volatile memory element 70 in which the pinhole 71a is formed. The heat generation region is therefore restricted to the vicinity of the pinhole 71a.

The coefficient of thermal conductivity of the chalcogenide material that forms the recording layers 11-1, 11-2 is about ⅓ that of a silicon oxide film. Therefore, the recording layer 11-1 positioned below the thin-film insulating layer 71 serves to inhibit heat transfer from the heat generation region to the side of the lower electrode 12, and the recording layer 11-2 positioned above the thin-film insulating layer 71 serves to inhibit heat transfer from the heat generation region to the side of the upper electrode 13. This makes it possible to obtain extremely high thermal efficiency in the present embodiment.

The method for manufacturing the non-volatile memory element 70 according to the present embodiment will next be described.

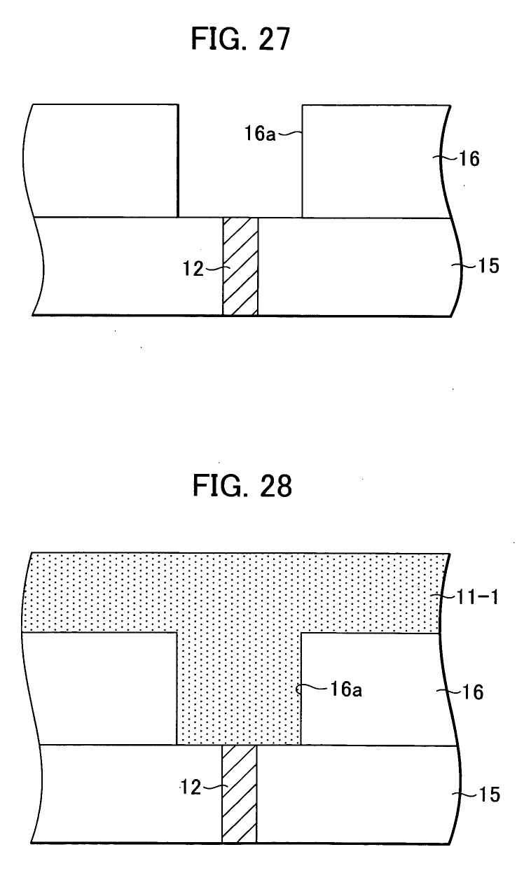

FIGS. 27 through 31 are schematic sectional views showing the, sequence of steps for manufacturing the non-volatile memory element 70.

First, as shown in FIG. 27, a lower electrode 12 is embedded in a first interlayer insulation film 15, after which a second interlayer insulation film 16 is formed on the first interlayer insulation film 15. A through-hole 16a is then formed in the second interlayer insulation film 16, and the upper surface of the lower electrode 12 is exposed.

A recording layer 11-1 is then formed on the second interlayer insulation film 16 as shown in FIG. 28. The thickness of the recording layer 11-1 is set during film formation so as to be small enough that the through-hole 16a can be almost completely filled.

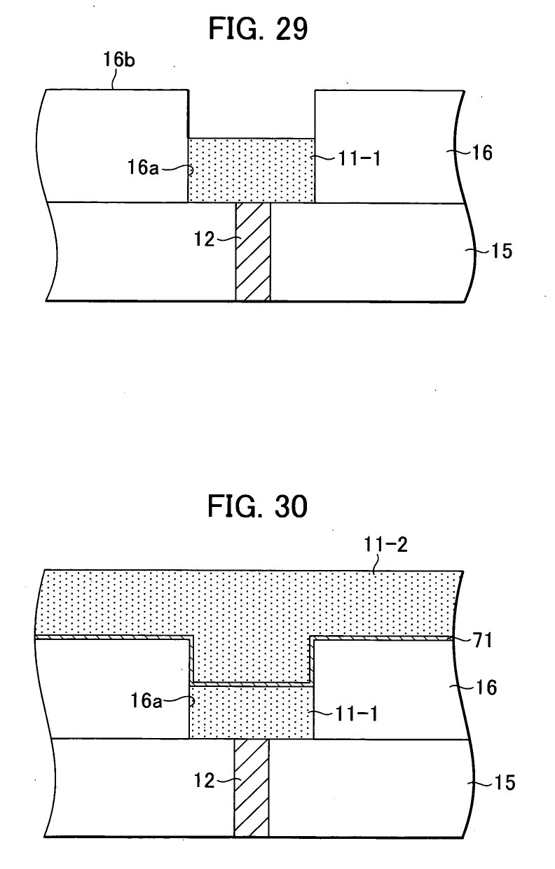

The recording layer 11-1 is then etched back until the upper surface 16b of the interlayer insulation film 16 is exposed as shown in FIG. 29. A state is thereby attained in which the recording layer 11-1 remains only in the bottom portion of the through-hole 16a.

A thin-film insulating layer 71 for covering the upper surface of the recording layer 11-1 is then formed as shown in FIG. 30. A sputtering method, a thermal CVD method, a plasma CVD method, an ALD method, or another method may be used to form the thin-film insulating layer 71. A method is preferably selected that has a minimal thermal/atmospheric effect on the chalcogenide material so as not to alter the properties of the chalcogenide material constituting the recording layer 11-1. A recording layer 11-2 is then formed with a thickness adequate to completely fill the through-hole 16a.

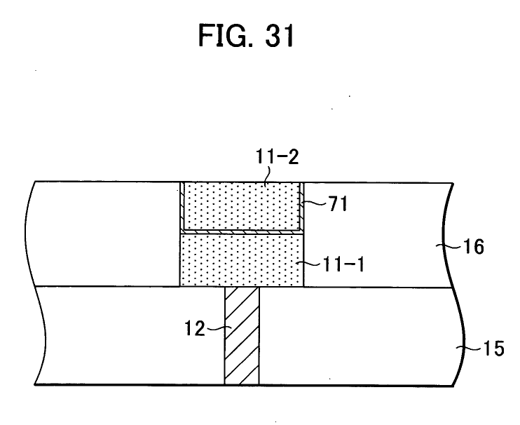

The recording layer 11-2 is then polished by CMP or another method, and the recording layer 11-2 formed on the outside of the through-hole 16a is removed, as shown in FIG. 31. A state is thereby attained in which the recording layer 11-1 and recording layer 11-2 are embedded inside the through-hole 16a, and the thin-film insulating layer 71 is interposed between these recording layers. When the recording layer 11-2 is polished, the thin-film insulating layer 71 formed on the upper surface of the second interlayer insulation film 16 may be entirely removed or allowed to remain, as shown in FIG. 31.

As shown in FIG. 26, the protective insulation film 17 and third interlayer insulation film 72 are then formed on the second interlayer insulation film 16, and the through-hole 72a is formed so that only a portion of the upper surface 11t of the recording layer 11-2 is exposed. Since the upper surface lit of the recording layer 11-2 is covered by the protective insulation film 17 at this time, it becomes possible to minimize the damage sustained by the recording layer 11 during formation of the through-hole 72a, as described above. After the upper electrode 13 is formed inside this through-hole 72a, the bit line 14 is formed on the third interlayer insulation film 72 and patterned in a prescribed shape to complete the non-volatile memory element 70 according to the present embodiment.

Before the actual use of the device as memory, a high voltage is applied across the lower electrode 12 and upper electrode 13 to induce dielectric breakdown of the thin-film insulating layer 71 and form a pinhole 71a. Since the recording layer 11-1 and recording layer 11-2 are thereby connected via the pinhole 71a provided to the thin-film insulating layer 71, the vicinity of this pinhole 71a becomes a heat generation region (heat generation point).

In the non-volatile memory element 70 according to the present embodiment thus configured, the pinhole 71a formed in the thin-film insulating layer 71 by dielectric breakdown is used as a current path, and an extremely minute current path can therefore be formed whose size is not dependent on the precision of a lithography process. Since the thin-film insulating layer 71 in which the pinhole 71a is formed is held between the two recording layers 11-1, 11-2, heat transfer to the side of the lower electrode 12 and heat transfer to the side of the upper electrode 13 are both effectively inhibited. As a result, it becomes possible to obtain extremely high thermal efficiency.

The present invention is in no way limited to the aforementioned embodiments, but rather various modifications are possible within the scope of the invention as recited in the claims, and naturally these modifications are included within the scope of the invention.

What is claimed is:

1. A non-volatile memory element comprising:
a recording layer that includes a phase change material;
a lower electrode provided in contact with said recording layer;
an upper electrode provided in contact with a portion of an upper surface of said recording layer;
a protective insulation film provided in contact with another portion of said upper surface of said recording layer; and
an interlayer insulation film provided on said protective insulation film.

2. The non-volatile memory element as claimed in claim 1, wherein said protective insulation film and said interlayer insulation film are made of different materials from each other.

3. The non-volatile memory element as claimed in claim 1, wherein
a through-hole is formed in said protective insulation film and said interlayer insulation film; and
said upper electrode is in contact with said portion of said upper surface of said recording layer via said through-hole.

4. The non-volatile memory element as claimed in claim 3, wherein
said upper electrode is formed in at least a wall surface portion of said through-hole; and
a buried member having a lower heat transfer coefficient than said upper electrode is provided to a region surrounding said upper electrode inside said through-hole.

5. The non-volatile memory element as claimed in claim 3, further comprising a bit line provided on said upper electrode; wherein said through-hole has a shape elongated in an extension direction of said bit line.

6. The non-volatile memory element as claimed in claim 3, wherein said through-hole is tapered.

7. The non-volatile memory element as claimed in claim 3, further comprising sidewalls formed in at least a wall surface portion of said through-hole;
wherein said upper electrode is formed in a region surrounded by said sidewalls.

8. The non-volatile memory element as claimed in claim 5, wherein said upper electrode is continuously provided along said bit line.

9. The non-volatile memory element as claimed in claim 5, wherein a planar shape of said upper electrode is ring-shaped.

10. The non-volatile memory element as claimed in claim 9, wherein said upper electrode is provided in common with an adjacent other recording layer connected to said bit line.

11. The non-volatile memory element as claimed in claim 9, wherein upper electrodes, each corresponding to adjacent bit lines, are disposed in a position displaced from an extension direction of said bit lines.

12. The non-volatile memory element as claimed in claim 1, wherein
said recording layer includes at least a first portion and a second portion; and
a thin-film insulating layer is provided between said first portion and said second portion.

13. The non-volatile memory element as claimed in claim 12, wherein
said lower electrode is provided in contact with said first portion of said recording layer; and
said upper electrode is provided in contact with said second portion of said recording layer.

14. The non-volatile memory element as claimed in claim 12, wherein dielectric breakdown is induced in said thin-film insulating layer.

15. A method for manufacturing a non-volatile memory element, comprising:
a first step for forming a recording layer that includes a phase change material;
a second step for patterning said recording layer while an upper surface of said recording layer is entirely covered by a protective insulation film;
a third step for exposing a portion of said upper surface of said recording layer by removing a portion of at least said protective insulation film; and
a fourth step for forming an upper electrode in contact with said portion of said upper surface of said recording layer.

16. The method for manufacturing a non-volatile memory element as claimed in claim 15, further comprising a step for forming an interlayer insulation film on said protective insulation film after performing said second step and prior to performing said third step.

17. The method for manufacturing a non-volatile memory element as claimed in claim 16, wherein said third step includes a step for exposing said portion of said upper surface of said recording layer by forming a through-hole in said protective insulation film and said interlayer insulation film.

18. The method for manufacturing a non-volatile memory element as claimed in claim 17, wherein said third step comprises a step for forming sidewalls in an inner wall of said through-hole.

19. The method for manufacturing a non-volatile memory element as claimed in claim 15, wherein
said third step comprises a step for forming a sidewall-forming insulation film whose end portion in a planar direction traverses said upper surface of said recording layer; and a step for exposing said portion of said upper surface of said recording layer by removing a portion of said protective insulation film using said sidewall-forming insulation film as a mask; and
said fourth step comprises a step for forming an upper electrode which covers said portion of said upper surface of said recording layer and at least a side surface of said sidewall-forming insulation film; and a step for etching back said upper electrode.

20. The method for manufacturing a non-volatile memory element as claimed in claim 19, wherein said end in a planar direction of said sidewall-forming insulation film traverses said upper surfaces of two or more adjacent recording layers.

21. A method for manufacturing a non-volatile memory element, comprising:
a first step for forming a recording layer that includes a phase change material;
a second step for covering entirely an upper surface of said recording layer with a protective insulation film and an interlayer insulation film;
a third step for exposing a portion of said upper surface of said recording layer by forming a through-hole in said protective insulation film and said interlayer insulation film; and
a fourth step for forming an upper electrode in contact with said portion of said upper surface of said recording layer.

22. The method for manufacturing a non-volatile memory element as claimed in claim 21, wherein said third step comprises
a step for etching said interlayer insulation film under conditions whereby a higher etching rate is obtained than in the conditions of etching said protective insulation film; and
a step for etching said protective insulation film under conditions whereby a higher etching rate is obtained than in the conditions of etching said recording layer.

23. The method for manufacturing a non-volatile memory element as claimed in claim 21, wherein said first step comprises
a step for forming a first portion of said recording layer;
a step for forming a thin-film insulating layer on said first portion of said recording layer; and
a step for forming a second portion of said recording layer on said thin-film insulating layer.

24. The method for manufacturing a non-volatile memory element as claimed in claim 23, further comprising a step for inducing dielectric breakdown of said thin-film insulation film.
